(19) United States
(12) Patent Application Publication
(10) Pub. No.: US 2025/0372150 A1
(43) Pub. Date: Dec. 4, 2025

(54) CLOCK SIGNAL GENERATOR GENERATING FOUR-PHASE CLOCK SIGNALS

(71) Applicant: MICRON TECHNOLOGY, INC., Boise, ID (US)

(72) Inventors: HIROSHI SHIMIZU, Sagamihara (JP); MIEKO KOJIMA, Hino (JP)

(73) Assignee: MICRON TECHNOLOGY, INC., Boise, ID (US)

(21) Appl. No.: 19/210,535

(22) Filed: May 16, 2025

Related U.S. Application Data
(60) Provisional application No. 63/653,120, filed on May 29, 2024.

(51) Int. Cl. G11C 11/4076; G11C 11/4074; G11C 11/4096

(52) U.S. Cl. CPC G11C 11/4076; G11C 11/4074; G11C 11/4096

(57) ABSTRACT

An example apparatus includes a clock driver circuit block having a first region on which a dividing circuit generating a divided clock signal is located, a second region on which a write clock driver outputting a write clock signal is located, a third region on which a first read clock driver outputting a first read clock signal having higher frequency is located, and a fourth region on which a second read clock driver outputting a second read clock signal having lower frequency is located. The distance between the first region and the third region is longer than the distance between the first region and the second region and shorter than the distance between the first region and the fourth region.

### CROSS-REFERENCE TO RELATED APPLICATIONS

This application claims the filing benefit of U.S. Provisional Application No. 63/653,120, filed May 29, 2024. This application is incorporated by reference herein in its entirety and for all purposes.

### BACKGROUND

There is a case where a semiconductor device such as a DRAM includes a parallel-serial conversion circuit that converts parallel read data into serial read data and a serial-parallel conversion circuit that converts serial write data into parallel write data. The parallel-serial conversion circuit performs a parallel-serial conversion operation in synchronization with read clock signals each having a different phase from one another. The serial-parallel conversion circuit performs a serial-parallel conversion operation in synchronization with write clock signals having a different phase from one another.

However, when the length of clock lines becomes long, it is necessary to make the size of a driver circuit that drives clock signals larger and the consumption current thereof is increased. In order to reduce the consumption current, there is conceived a method in which a driver circuit that drives a high-frequency clock signal and another driver circuit that drives a low-frequency clock signal are provided and any one of the driver circuits is used by switching operation modes. In this case, there is an issue as to how to lay out the driver circuit that drives a high-frequency clock signal and the driver circuit that drives a low-frequency clock signal.

### BRIEF DESCRIPTION OF THE DRAWINGS

FIG. 1 is a schematic plan view showing a layout of a semiconductor device according to the present disclosure;

FIG. 2 is a layout diagram showing a configuration of an I/O control circuit;

FIG. 3 is a block diagram showing a configuration of the I/O control circuit;

FIG. 4 is a schematic plan view showing a layout of a clock signal generation circuit;

FIG. 5 is a waveform diagram of high-speed read clock signals;

FIG. 6 is a circuit diagram of a clock driver,

FIG. 7 is a schematic plan view for explaining positions of respective circuits included in the clock signal generation circuit;

FIG. 8 is a schematic plan view for explaining a layout of the I/O control circuit;

FIG. 9A is a plan view showing a layout of a clock signal generation circuit according to a first modification;

FIG. 9B is a plan view showing a layout of a clock signal generation circuit according to a second modification;

FIG. 9C is a plan view showing a layout of a clock signal generation circuit according to a third modification;

FIG. 10 is a circuit diagram of a power supply switching circuit;

FIG. 11A is a plan view showing a layout of the clock signal generation circuit and the power supply switching circuit;

FIG. 11B is a schematic diagram showing power supply lines provided on the clock signal generation circuit and the power supply switching circuit;

FIG. 12A is a plan view showing a layout of the clock signal generation circuit and the power supply switching circuit according to the first modification; and

FIG. 12B is a plan view showing a layout of the clock signal generation circuit and the power supply switching circuit according to the second modification.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

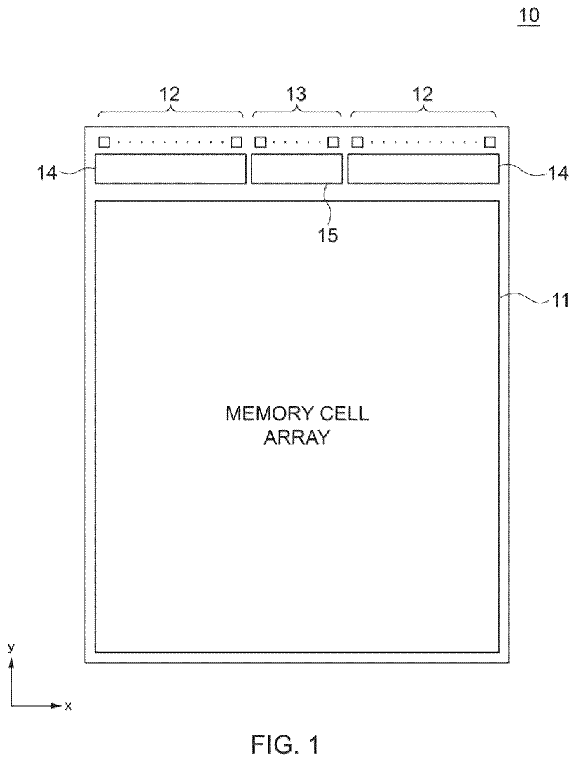

FIG. 1 is a schematic plan view showing a layout of a semiconductor device according to the present disclosure. A semiconductor device 10 according to the present disclosure is an LPDDR5 DRAM. As shown in FIG. 1, the semiconductor device 10 includes a memory cell array 11, a plurality of data terminals 12, and a plurality of command address terminals 13. The terminals 12 and 13 are arrayed along one side of the semiconductor device 10 extending in an x direction. Other than these elements, a power supply terminal and the like are also present in the semiconductor device 10. The data terminals 12 are arrayed in two locations in a divided manner and the command address terminals 13 are arrayed between the divided data terminals 12. The memory cell array 11 and the data terminals 12 are coupled to each other via an I/O control circuit 14, and the memory cell array 11 and the command address terminals 13 are coupled to each other via an access control circuit 15. When a read command and an address signal corresponding thereto are input from one of the command address terminals 13, read data read out from a designated address in the memory cell array 11 is output to one of the data terminals 12 via the I/O control circuit 14. Further, when a write command and an address signal corresponding thereto are input from one of the command address terminals 13, write data input to one of the data terminals 12 is written in a designated address in the memory cell array 11 via the I/O control circuit 14.

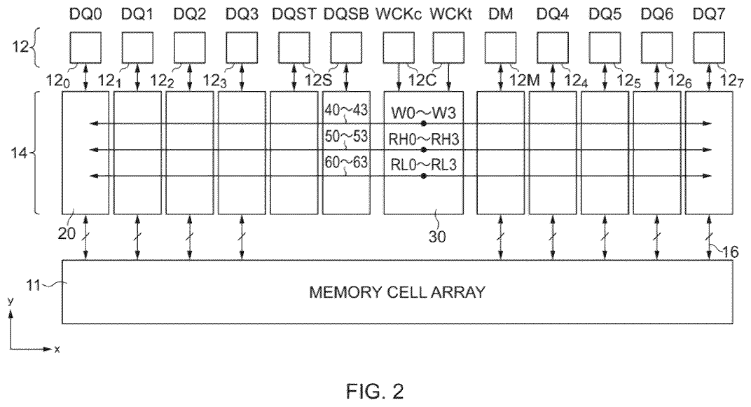

As shown in FIG. 2, each of the data terminals 12 includes terminals 120 to 127 that respectively input and output data DQ0 to DQ7, a terminal 12M that inputs and outputs a data mask signal, terminals 12S that respectively input and output complementary strobe signals DQST and DQSB, and terminals 12C to which complementary clock signals WCKt and WCKc are respectively input. An I/O control circuit 20 is allocated to each of the terminals 120 to 127 and 12M. The I/O control circuit 20 is coupled to the memory cell array 11 via a read/write bus 16. The I/O control circuits 20 are arrayed along the x-coordinate of a corresponding data terminal 12 so that read data and write data flow in a y direction. The x-direction and the y-direction may be orthogonal to each other.

The clock signals WCKt and WCKc are input to a clock signal generation circuit 30. The clock signal generation circuit 30 generates, based on the clock signals WCKt and WCKc, write clock signals W0 to W3, high-speed read clock signals RH0 to RH3, and low-speed read clock signals RL0 to RL3. The write clock signals W0 to W3 have a different phase from one another by 90° and each of the write clock signals W0 to W3 is supplied to the I/O control circuit 20 via respective write clock lines 40 to 43. The high-speed read clock signals RH0 to RH3 have a different phase from one another by 90° and each of the read clock signals RH0 to RH3 is supplied to the I/O control circuit 20 via respective read clock lines 50 to 53. The low-speed read clock signals RL0 to RL3 have a different phase from one another by 90° and each of the read clock signals RL0 to RL3 is supplied to the I/O control circuit 20 via respective read clock lines 60 to 63. Each of the write clock lines 40 to 43, the read clock lines 50 to 53, and the read clock lines 60 to 63 extends in the y direction.

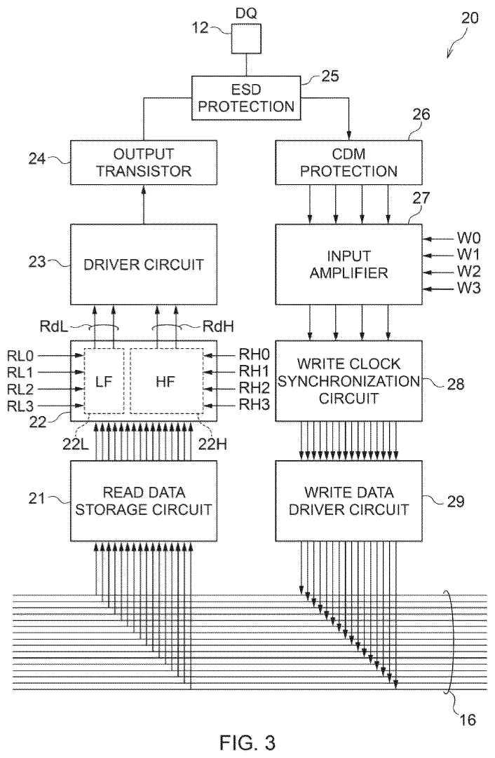

FIG. 3 is a block diagram showing a configuration of the I/O control circuit 20. The I/O control circuit 20 includes a read-system circuit constituted of a read data storage circuit 21, a read clock synchronization circuit 22, a driver circuit 23, and an output transistor 24 and a write-system circuit constituted of a CDM protection circuit 26, an input amplifier 27, a write clock synchronization circuit 28, and a write data output circuit 29. An ESD protection circuit 25 is provided in the vicinity of the data terminal 12.

The read data storage circuit 21 stores therein parallel read data supplied from the read/write bus 16 and supplies the read data to the read clock synchronization circuit 22. The read clock synchronization circuit 22 is constituted of a read clock synchronization circuit 22H that performs operations in synchronization with the high-speed read clock signals RH0 to RH3 and a read clock synchronization circuit 22L that performs operations in synchronization with the low-speed read clock signals RL0 to RL3. The read clock synchronization circuit 22H performs serial conversion on parallel read data based on the high-speed read clock signals RH0 to RH3 to generate complementary read data RdH. The read clock synchronization circuit 22L performs serial conversion on parallel read data based on the low-speed read clock signals RL0 to RL3 to generate complementary read data RdL. The driver circuit 23 drives the output transistor 24 based on the read data RdH or RdL, thereby outputting serial write data DQ from the data terminal 12.

Meanwhile, in a write operation, the write data DQ input to the data terminal 12 is supplied to the input amplifier 27 via the CDM protection circuit 26. The input amplifier 27 converts the serial write data DQ into parallel 4-bit write data DQ based on the write clock signals W0 to W3. The parallel 4-bit write data DQ is further converted into parallel 16-bit write data DQ by the write clock synchronization circuit 28 and is output to the read/write bus 16 via the write data output circuit 29.

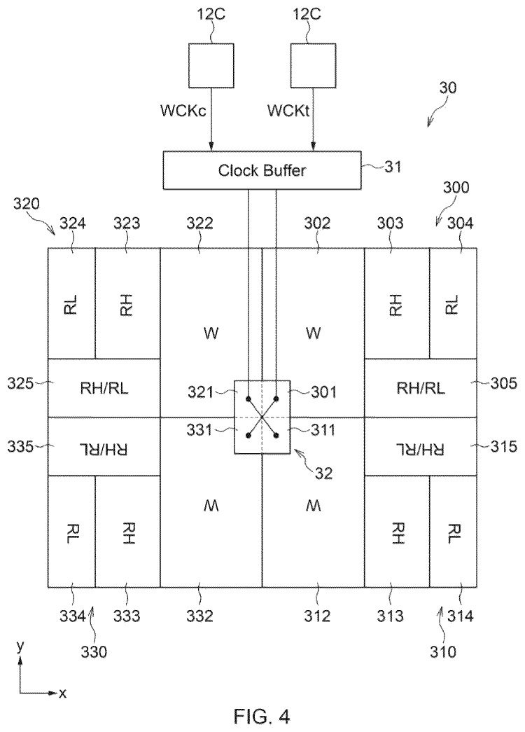

FIG. 4 is a schematic plan view showing a layout of the clock signal generation circuit 30. As shown in FIG. 4, the clock signal generation circuit 30 includes a clock buffer 31 that buffers the complementary clock signals WCKt and WCKc, a dividing circuit 32 that divides the complementary clock signals WCKt and WCKc output from the clock buffer 31, and four clock drivers 300, 310, 320, and 330. The dividing circuit 32 is located on regions 301, 311, 321, and 331. The clock signals WCKt and WCKc have their frequencies switched according to operation modes. That is, the frequencies of the clock signals WCKt and WCKc are set to be high at the time of a high-speed operation and the frequencies of the clock signals WCKt and WCKc are set to be low at the time of a low-speed operation. Accordingly, frequencies of divided clock signals output from the dividing circuit 32 are also changed according to operation modes.

The clock driver 300 is a circuit that generates the write clock signal W0, the high-speed read clock signal RH0, and the low-speed read clock signal RL0. Circuits constituting the clock driver 300 are respectively located on regions 302 to 305. The clock driver 310 is a circuit that generates the write clock signal W1, the high-speed read clock signal RH1, and the low-speed read clock signal RL1. Circuits constituting the clock driver 310 are respectively located on regions 312 to 315. The clock driver 320 is a circuit that generates the write clock signal W2, the high-speed read clock signal RH2, and the low-speed read clock signal RL2. Circuits constituting the clock driver 320 are respectively located on regions 322 to 325. The clock driver 330 is a circuit that generates the write clock signal W3, the high-speed read clock signal RH3, and the low-speed read clock signal RL3. Circuits constituting the clock driver 330 are respectively located on regions 332 to 335.

The region 301 is arranged to penetrate in the region 302 included in the clock driver 300, and the region 301 and the region 302 form a substantially rectangular shape when these regions are put together. As described later, a circuit (W) that generates the write clock signal W0 is located on the region 302. Further, the regions 303 to 305 included in the clock driver 300 form a substantially rectangular shape all together. The rectangle formed of the regions 301 and 302 and the rectangle formed of the regions 303 to 305 are adjacent to each other in the x direction and the widths of these rectangles in the y direction are substantially the same. The region 303 is sandwiched between the region 302 and the region 305 in the x direction. As described later, a circuit (RH) that generates the high-speed read clock signal RH0 is located on the region 303, a circuit (RL) that generates the low-speed read clock signal RL0 is located on the region 304, and a common circuit (RH/RL) that generates the high-speed read clock signal RH0 and the low-speed read clock signal RL0 are located on the region 305. In some examples, the common circuit (RH/RL) may be understood as a read pre-stage circuit. Other clock drivers 310, 320, and 330 have a configuration same as that of the clock driver 300.

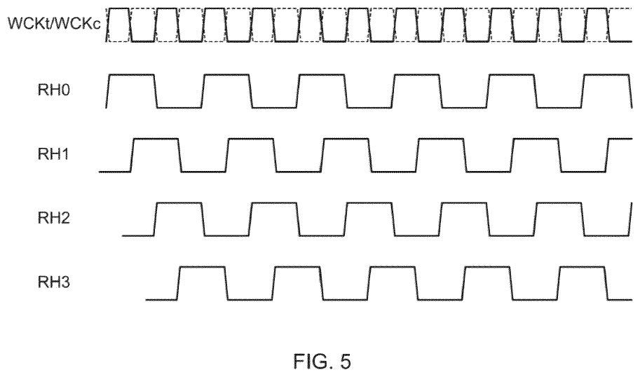

As shown in FIG. 5, each of the high-speed read clock signals RH0 to RH3 is a four-phase clock signal having a period as twice as that of the clock signals WCKt and WCKc, and the high-speed read clock signals RH0 to RH3 have a different phase from one another by 90°. This feature also applies to the write clock signals W0 to W3 and the low-speed read clock signals RL0 to RL3.

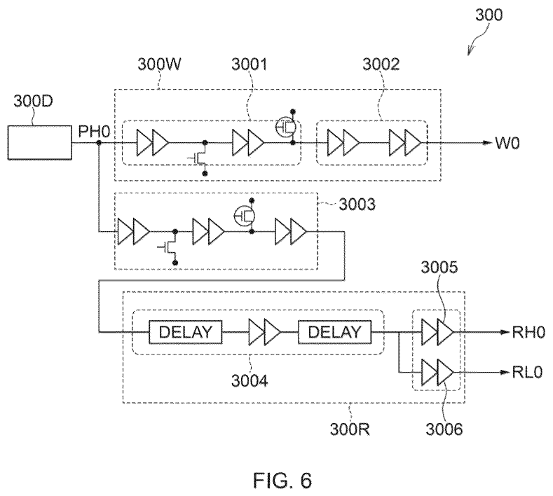

FIG. 6 is a circuit diagram of the clock driver 300. As shown in FIG. 6, the clock driver 300 includes a write clock driver 300W, a read clock driver 300R, and a buffer circuit 3003. The write clock driver 300W includes a front stage circuit 3001 that receives a divided clock signal PH0 supplied from a dividing circuit 300D and an output circuit 3002 that generates the write clock signal W0 based on a write pre-clock signal as an output from the front stage circuit 3001. In some examples, the front stage circuit 3001 may be understood as a pre-stage circuit. The buffer circuit 3003 buffers the divided clock signal PH0 to supply the divided clock signal PH0 to the read clock driver 300R. The read clock driver 300R includes a front stage circuit 3004 that receives the divided clock signal PH0 having been buffered by the buffer circuit 3003 and output circuits 3005 and 3006 that respectively generate the high-speed read clock signal RH0 and the low-speed read clock signal RL0 based on a read pre-clock signal as an output from the front stage circuit 3004. In some examples, the front stage circuit 3004 may be understood as a pre-stage circuit. Other clock drivers 310, 320, and 330 have a circuit configuration same as that of the clock driver 300.

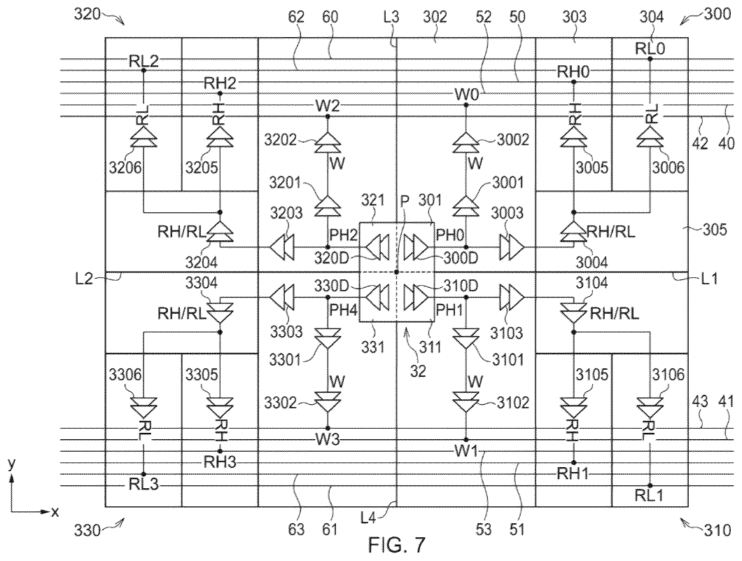

FIG. 7 is a schematic plan view for explaining positions of respective circuits included in the clock signal generation circuit 30. As shown in FIG. 7, the dividing circuit 300D is located on the region 301 in the dividing circuit 32. The divided clock signal PH0 output from the dividing circuit 300D is branched in the region 302. One of the divided clock signals PH0 branched in the region 302 is sequentially transmitted to the front stage circuit 3001 and the output circuit 3002 arrayed in this order in the y direction in the region 302. The write clock signal W0 generated by the output circuit 3002 is supplied to the write clock line 40 passing above the region 302. The other one of the divided clock signals PH0 branched in the region 302 is supplied to the front stage circuit 3004 located on the region 305 via the buffer circuit 3003 located in the region 302. The divided clock signal PH0 output from the front stage circuit 3004 is branched in the region 305. One of the divided clock signals PH0 branched in the region 305 is supplied to the output circuit 3005 located on the region 303. The output circuit 3005 is a clock driver used for high-speed operations. The high-speed read clock signal RH0 generated by the output circuit 3005 is supplied to the read clock line 50 passing above the region 303. The other one of the divided clock signals PH0 branched in the region 305 is supplied to the output circuit 3006 located on the region 304. The output circuit 3006 is a clock driver used for high-speed operations. The low-speed read clock signal RL0 generated by the output circuit 3006 is supplied to the read clock line 60 passing above the region 304.

As described above, the divided clock signal PH0 output from the dividing circuit 300D is output as the write clock signal W0 as it passes through the front stage circuit 3001 and the output circuit 3002 located on the region 302. Further, the divided clock signal PH0 output from the dividing circuit 300D is output as the high-speed read clock signal RH0 as it passes through the buffer circuit 3003 located on the region 302, the front stage circuit 3004 located on the region 305, and the output circuit 3005 located on the region 303. Further, the divided clock signal PH0 output from the dividing circuit 300D is output as the low-speed read clock signal RL0 as it passes through the buffer circuit 3003 located on the region 302, the front stage circuit 3004 located on the region 305, and the output circuit 3006 located on the region 304. Here, since the buffer circuit 3003 and the front stage circuit 3004 are located adjacently to each other in the x direction, the positions of the front stage circuit 3004 and the output circuit 3005 in the x direction substantially match each other. Accordingly, a clock path coupling the front stage circuit 3004 and the output circuit 3005 extends in a substantially linear manner in the y direction and only a small portion of the clock path extends in the x direction. On the other hand, the positions of the front stage circuit 3004 and the output circuit 3006 in the x direction are different from each other, so that a clock path coupling the front stage circuit 3004 and the output circuit 3006 includes a portion extending in the x direction as well as a portion extending in the y direction more than those of the clock path coupling the front stage circuit 3004 and the output circuit 3005. As a result, a clock path reaching from the dividing circuit 300D to the output circuit 3005 is shorter than a clock path reaching from the dividing circuit 300D to the output circuit 3006, and therefore delay of the high-speed read clock signal RH0 is prevented and the consumption current of the semiconductor device 10 is reduced. Further, since the read clock line 50 that conveys the high-speed read clock signal RH0 is located at a position nearer than the read clock line 60 that conveys the low-speed read clock signal RL0 to the region 305, the line coupling the front stage circuit 3004 and the output circuit 3005 in the y direction is also shortened. Further, since the region 301 and the region 302 are adjacent to each other, a clock path reaching from the dividing circuit 300D to the output circuit 3002 is much shorter than the clock path reaching from the dividing circuit 300D to the output circuit 3005.

The layout of the clock driver 300 included in the clock signal generation circuit 30 is as described above. Other clock drivers 310, 320, and 330 also have a layout same as that of the clock driver 300 described above.

First, the clock driver 310 has a layout symmetrical with the clock driver 300 about a border line L1 constituting a border line between the clock driver 300 and the clock driver 310 and extending in the x direction as a reference. A divided clock signal PH1 output from a dividing circuit 310D located on the region 301 of the dividing circuit 32 is branched in the region 312, the write clock signal W1 is generated with a write clock path constituted of a front stage circuit 3101 and an output circuit 3102, and the high-speed read clock signal RH1 and the low-speed read clock signal RL1 are generated with a write clock path constituted of a buffer circuit 3103, a front stage circuit 3104, and output circuits 3105 and 3106. The write clock signal W1 is supplied to a write clock line 41. The high-speed read clock signal RH1 and the low-speed read clock signal RL1 are respectively supplied to read clock lines 51 and 61.

The clock driver 320 has a layout symmetrical with the clock driver 300 about a border line L3 constituting a border line between the clock driver 300 and the clock driver 310 and extending in the y direction as a reference. A divided clock signal PH2 output from a dividing circuit 320D located on the region 302 of the dividing circuit 32 is branched in the region 322, the write clock signal W2 is generated with a write clock path constituted of a front stage circuit 3201 and an output circuit 3202, and the high-speed read clock signal RH2 and the low-speed read clock signal RL2 are generated with a write clock path constituted of a buffer circuit 3203, a front stage circuit 3204, and output circuits 3205 and 3206. The write clock signal W2 is supplied to a write clock line 42. The high-speed read clock signal RH2 and the low-speed read clock signal RL2 are respectively supplied to read clock lines 52 and 62.

The clock driver 330 has a layout symmetrical with the clock driver 320 about a border line L2 constituting a border line between the clock driver 320 and the clock driver 330 and extending in the x direction as a reference. The clock driver 330 also has a layout symmetrical with the clock driver 310 about a border line LA constituting a border line between the clock driver 310 and the clock driver 330 and extending in the y direction as a reference. A divided clock signal PH3 output from a dividing circuit 330D located on the region 303 of the dividing circuit 32 is branched in the region 332, the write clock signal W3 is generated with a write clock path constituted of a front stage circuit 3301 and an output circuit 3302, and the high-speed read clock signal RH3 and the low-speed read clock signal RL3 are generated with a write clock path constituted of a buffer circuit 3303, a front stage circuit 3304, and output circuits 3305 and 3306. The write clock signal W3 is supplied to a write clock line 43. The high-speed read clock signal RH3 and the low-speed read clock signal RL3 are respectively supplied to read clock lines 53 and 63.

When a center point P positioned at the center of the dividing circuit 32 and constituting an end of each of the border lines L1 to L4 described above is defined, the clock driver 300 and the clock driver 330 are rotationally symmetric about the center point P, and the clock driver 310 and the clock driver 320 are rotationally symmetric about the center point P.

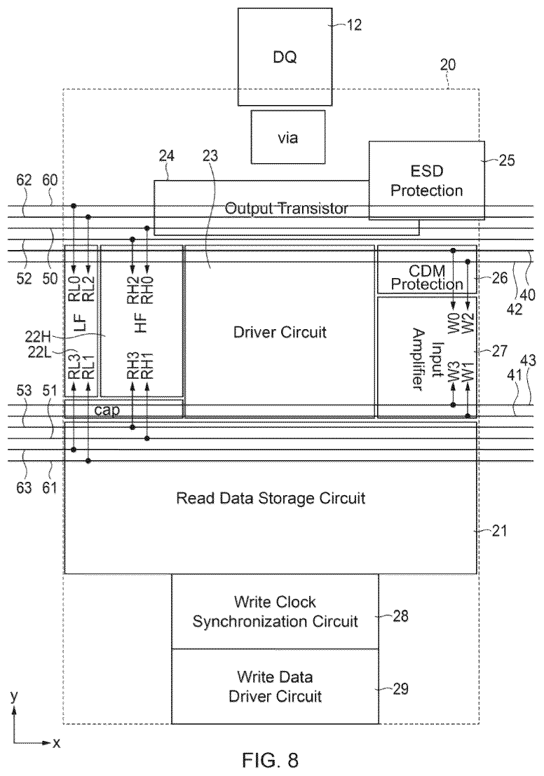

FIG. 8 is a schematic plan view for explaining a layout of the I/O control circuit 20. As shown in FIG. 8, the read data storage circuit 21, the read clock synchronization circuit 22, the output transistor 24, the CDM protection circuit 26, and the input amplifier 27 included in the I/O control circuit 20 are arranged so as to surround the driver circuit 23. Further, a line group formed of the write clock lines 40 and 42 and the read clock lines 50, 52, 60, and 62 is located on a +y direction side as viewed from the center of the driver circuit 23, and a line group formed of the write clock lines 41 and 43 and the read clock lines 51, 53, 61, and 63 is located on a −y direction side as viewed from the center of the driver circuit 23. The write clock signals W0 and W2 respectively conveyed on the write clock lines 40 and 42 are supplied to the input amplifier 27 via a clock path branched in the −y direction. The write clock signals W1 and W3 respectively conveyed on the write clock lines 41 and 43 are supplied to the input amplifier 27 via a clock path branched in the +y direction.

The read clock synchronization circuit 22H that constitutes the read clock synchronization circuit 22 is located nearer than the read clock synchronization circuit 22L that constitutes the read clock synchronization circuit 22 to the driver circuit 23. The high-speed read clock signals RH0 and RH2 respectively conveyed on the read clock lines 50 and 52 are supplied to the read clock synchronization circuit 22H via the clock path branched in the −y direction. The high-speed read clock signals RH1 and RH3 respectively conveyed on the read clock lines 51 and 53 are supplied to the read clock synchronization circuit 22H via a clock path branched in a +y direction. In this manner, since the read clock synchronization circuit 22H is located adjacently to the driver circuit 23, the distance between branched clock paths coupling the read clock synchronization circuit 22H and the driver circuit 23 is shortened, thereby preventing delay of the high-speed read clock signals RH0 to RH3 in a high-speed operation.

Further, the low-speed read clock signals RL0 and RL2 respectively conveyed on the read clock lines 60 and 62 are supplied to the read clock synchronization circuit 22L via the clock path branched in the −y direction. The low-speed read clock signals RL1 and RL3 respectively conveyed on the read clock lines 61 and 63 are supplied to the read clock synchronization circuit 22L via the clock path branched in the +y direction.

As described above, in the clock signal generation circuit 30 included in the semiconductor device 10 according to the present disclosure, as attention is paid on the clock driver 300, the output circuit 3005 that is used in a high-speed operation is located nearer than the output circuit 3006 that is used in a low-speed operation to the dividing circuit 300D. Accordingly, the clock path from the dividing circuit 300D to the output circuit 3005 is made shorter than the clock path from the dividing circuit 300D to the output circuit 3006, and thus delay of the high-speed read clock signal RH0 used in a high-speed operation can be prevented. This feature also applies to other clock drivers 310, 320, and 330.

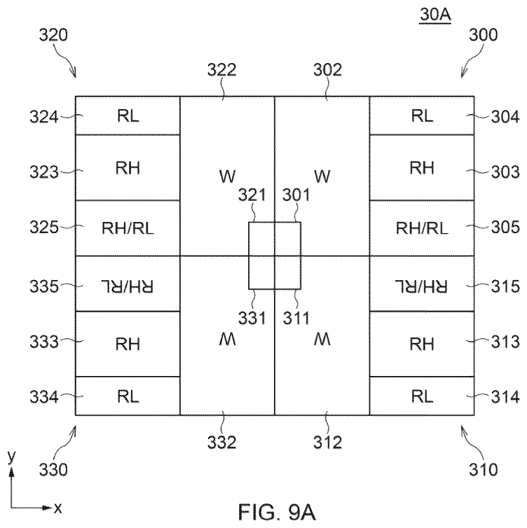

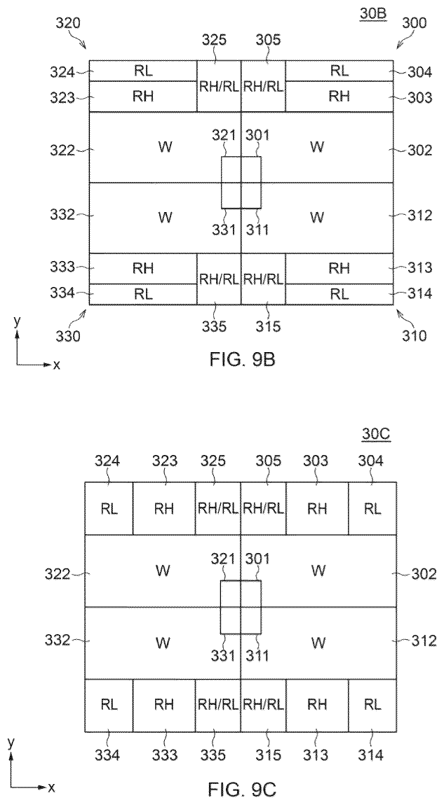

FIG. 9A is a plan view showing a layout of a clock signal generation circuit 30A according to a first modification. In the first modification shown in FIG. 9A, the feature that the region 303 and the region 304 included in the clock driver 300 are arrayed in the y direction is different from the layout shown in FIG. 4. Accordingly, the region 303 is sandwiched between the region 304 and the region 305 in the y direction. With this layout, it is possible to shorten the wiring distance between the front stage circuit 3004 located on the region 305 and the output circuit 3005 located on the region 303. This feature also applies to other clock drivers 310, 320, and 330.

FIG. 9B is a plan view showing a layout of a clock signal generation circuit 30B according to a second modification. In the second modification shown in FIG. 9B, the feature that the region 302 on which a write-system circuit is located and a block formed of the regions 303 to 305 on which a read-system circuit is located are arrayed in the y direction is different from the layout shown in FIG. 4. The region 303 is sandwiched between the region 304 and the region 305 in the y direction. Even with this layout, it is possible to make the clock path from the dividing circuit 300D to the output circuit 3005 shorter than the clock path from the dividing circuit 300D to the output circuit 3006. This feature also applies to other clock drivers 310, 320, and 330.

FIG. 9C is a plan view showing a layout of a clock signal generation circuit 30C according to a third modification. In the third modification shown in FIG. 9C, the feature that the region 303 and the region 304 included in the clock driver 300 are arrayed in the x direction is different from the layout shown in FIG. 9B. Accordingly, the region 303 is sandwiched between the region 304 and the region 305 in the x direction. With this layout, it is possible to shorten the wiring distance between the front stage circuit 3004 located on the region 305 and the output circuit 3005 located on the region 303. This feature also applies to other clock drivers 310, 320, and 330.

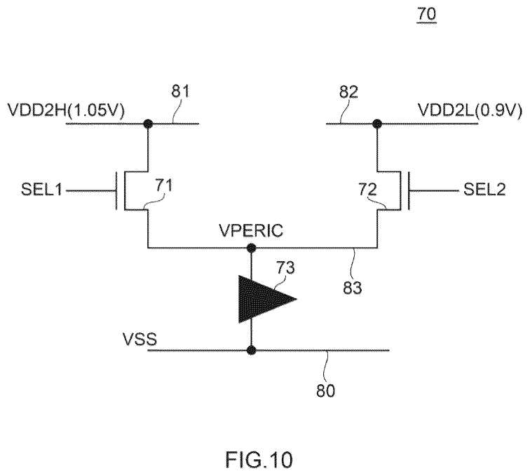

FIG. 10 is a circuit diagram of a power supply switching circuit 70. As shown in FIG. 10, the power supply switching circuit 70 includes a switch circuit 71 coupled between a power supply line 81 and a power supply line 83 and a switch circuit 72 coupled between a power supply line 82 and the power supply line 83. Each of the switch circuits 71 and 72 is formed of an N-channel MOS transistor. While each of the switch circuits 71 and 72 is shown as one transistor in FIG. 10, these circuits may have a configuration in which a plurality of transistors are coupled to one another in parallel. A selection signal SEL1 is supplied to a gate electrode of the transistor constituting the switch circuit 71. A selection signal SEL2 is supplied to a gate electrode of the transistor constituting the switch circuit 72. Each of the selection signal SEL1 and the selection signal SEL2 is activated exclusively. A power voltage VDD2H is supplied from outside to the power supply line 81. A power voltage VDD2L is supplied from outside to the power supply line 82. The levels of the power voltage VDD2H and the power voltage VDD2L are mutually different. As an example, the power voltage VDD2H is 1.05V and the power voltage VDD2L is 0.9V. The power supply line 83 is an internal power supply line used for supplying a power voltage VPERIC to a driver circuit 73. The driver circuit 73 is a circuit that constitutes the clock signal generation circuit 30 and is operated with a voltage between the power voltage VPERIC supplied to the power supply line 83 and a power voltage VSS supplied to the power supply line 80. Accordingly, when the selection signal SEL1 is activated, the circuit constituting the clock signal generation circuit 30 is operated with the power voltage VDD2H (=1.05V), and when the selection signal SEL2 is activated, the circuit constituting the clock signal generation circuit 30 is operated with the power voltage VDD2L (=0.9V). Therefore, the clock signal generation circuit 30 can be operated at a higher speed by activating the selection signal SEL1 and the consumption current of the clock signal generation circuit 30 can be reduced by activating the selection signal SEL2.

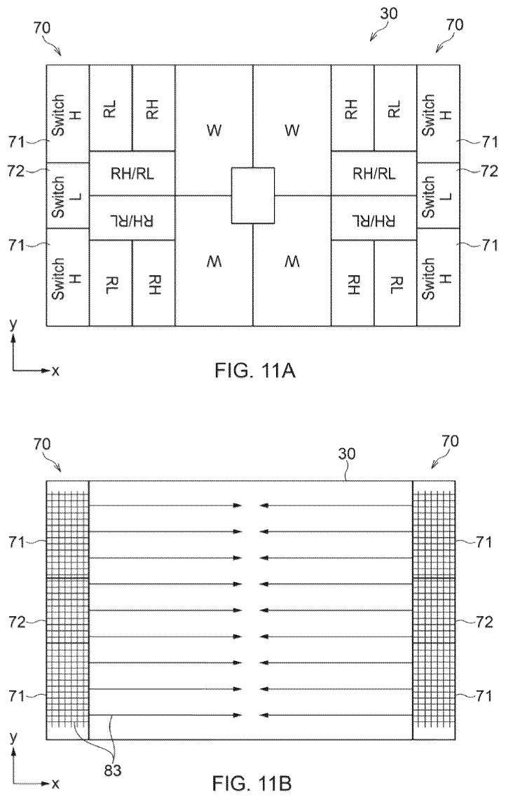

FIG. 11A is a plan view showing a layout of the clock signal generation circuit 30 and the power supply switching circuit 70. In the example shown in FIG. 11A, the power supply switching circuit 70 is located on both sides of the clock signal generation circuit 30 in the x direction. The switch circuits 71 included in the power supply switching circuit 70 are located in a separated manner in the y direction and the switch circuit 72 is located to be sandwiched between the two switch circuits 71. As shown in FIG. 11B, above the regions on which the switch circuits 71 and 72 are located, a plurality of power supply lines 83 are located in a mesh shape, thereby stabilizing the power voltage VPERIC. Further, the power voltage VRERIC is supplied from the power supply switching circuit 70 to each of the circuits constituting the clock signal generation circuit 30 via a plurality of power supply lines 83 extending in the x direction. In this manner, as power supply switching circuits 70 are located in a separated manner so as to sandwich the clock signal generation circuit 30 in the x direction and the power voltage VPERIC is supplied via a plurality of power supply lines 83 from both sides in the x direction, it is possible to supply the power voltage VPERIC to the clock signal generation circuit 30 in a stable manner.

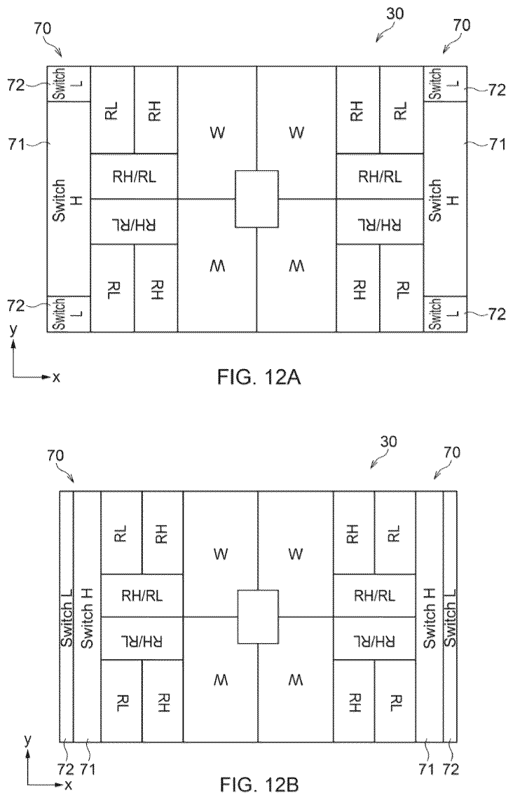

FIG. 12A is a plan view showing a layout of the clock signal generation circuit 30 and the power supply switching circuit 70 according to the first modification. In the first modification shown in FIG. 12A, the switch circuits 72 included in the power supply switching circuit 70 are located in a separated manner in the y direction and the switch circuit 71 is located to be sandwiched between two switch circuits 72. Even in this layout, it is possible to supply power voltage VPERIC to the clock signal generation circuit 30 in a stable manner.

FIG. 12B is a plan view showing a layout of the clock signal generation circuit 30 and the power supply switching circuit 70 according to the second modification. In the second modification shown in FIG. 12B, the switch circuit 71 is located on the inside nearer to the clock signal generation circuit 30 and the switch circuit 72 is located on the outside further from the clock signal generation circuit 30. Even in this layout, it is possible to supply the power voltage VPERIC to the clock signal generation circuit 30 in a stable manner.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising a plurality of clock driver circuit blocks, each of the plurality of clock driver circuit blocks divided into multiple regions which comprise:
a first region on which a dividing circuit is located;
a second region on which a write clock driver is located;
a third region on which a first read clock driver is located; and
a fourth region on which a second read clock driver is located,
wherein the dividing circuit is configured to generate a divided clock signal,
wherein the write clock driver is configured to output a write clock signal based on the divided clock signal,
wherein the first read clock driver is configured to output a first read clock signal having a first frequency based on the divided clock signal,
wherein the second read clock driver is configured to output a second read clock signal having a second frequency lower than the first frequency based on the divided clock signal, and
wherein a distance between the first region and the third region is longer than a distance between the first region and the second region and shorter than a distance between the first region and the fourth region.

2. The apparatus of claim 1, wherein the third region is arranged between the second region and the fourth region.

3. The apparatus of claim 1,
wherein each of the plurality of clock driver circuit blocks further comprises a fifth region on which a read pre-stage circuit is located, and
wherein the read pre-stage circuit is configured to distribute the divided clock signal to the first and second read clock drivers.

4. The apparatus of claim 3, wherein the third region is arranged between the fourth region and the fifth region.

5. The apparatus of claim 3, wherein the second region has a buffer circuit coupled between the dividing circuit and the read pre-stage circuit and configured to convey the divided clock signal to the read pre-stage circuit.

6. The apparatus of claim 5, wherein the second region further has a write pre-stage circuit coupled between the dividing circuit and the write clock driver without the buffer circuit interposed therebetween and configured to convey the divided clock signal to the write clock driver.

7. The apparatus of claim 3, wherein the third, fourth, and fifth regions form a read block having a rectangle shape.

8. The apparatus of claim 7,
wherein the second region and the read block are arranged adjacently to each other in a first direction, and
wherein a width of the second region in a second direction perpendicular to the first direction is substantially the same as a width of the read block in the second direction.

9. The apparatus of claim 1,
wherein the plurality of clock driver circuit blocks include first and second clock driver circuit blocks arranged adjacently to each other in a first direction,
wherein the divided clock signal in the first clock driver circuit block and the divided clock signal in the second clock driver circuit block are different in phase from each other, and
wherein the first and second clock driver circuit blocks are symmetrical about a first border line extending therebetween in a second direction perpendicular to the first direction.

10. The apparatus of claim 9,
wherein the plurality of clock driver circuit blocks further include third and fourth clock driver circuit blocks arranged adjacently to each other in the first direction,
wherein first and third clock driver circuit blocks are arranged adjacently to each other in the second direction,
wherein second and fourth clock driver circuit blocks are arranged adjacently to each other in the second direction,
wherein the divided clock signal in the first clock driver circuit block, the divided clock signal in the second clock driver circuit block, the divided clock signal in the third clock driver circuit block, and the divided clock signal in the fourth clock driver circuit block are different in phase from one another,
wherein the third and fourth clock driver circuit blocks are symmetrical about a second border line extending therebetween in the second direction,
wherein the first and third clock driver circuit blocks are symmetrical about a third border line extending therebetween in the first direction, and
wherein the second and fourth clock driver circuit blocks are symmetrical about a fourth border line extending therebetween in the first direction.

11. The apparatus of claim 10,
wherein the first and fourth clock driver circuit blocks are symmetrical about a center point that is an end of each of the first, second, third, and fourth border lines, and
wherein the second and third clock driver circuit blocks are symmetrical about the center point.

12. The apparatus of claim 1, further comprising first and second power supply circuits configured to supply a power voltage to the plurality of clock driver circuit blocks,
wherein the plurality of clock driver circuit blocks are arranged between the first and second power supply circuits, and
wherein each of the first and second power supply circuits includes a first switch circuit configured to supply the power voltage having a first voltage and a second switch circuit configured to supply the power voltage having a second voltage lower than the first voltage.

13. An apparatus comprising:
a first region on which a dividing circuit is located;
a second region on which a write clock driver circuit is located, the second region being arranged adjacently to the first region; and
a third region on which a read clock driver circuit is located, the third region being arranged adjacently to the second region so as not to be adjacent to the first region,
wherein the dividing circuit is configured to generate a divided clock signal,
wherein the write clock driver circuit includes:
a first pre-stage circuit coupled to the dividing circuit and configured to generate a write pre-clock signal based on the divided clock signal; and
a first output circuit coupled to the first pre-stage circuit and configured to generate a write clock signal based on the write pre-clock signal,
wherein the read clock driver circuit includes:
a second pre-stage circuit coupled to the dividing circuit and configured to generate a read pre-clock signal based on the divided clock signal;
a second output circuit coupled to the second pre-stage circuit and configured to generate a first read clock signal having a first frequency based on the read pre-clock signal; and
a third output circuit coupled to the second pre-stage circuit and configured to generate a second read clock signal having a second frequency lower than the first frequency based on the read pre-clock signal, and
wherein a distance between the second pre-stage circuit and the second output circuit is shorter than a distance between the second pre-stage circuit and the third output circuit.

14. The apparatus of claim 13,
wherein the third region includes a first sub-region on which the second pre-stage circuit is located, a second sub-region on which the second output circuit is located, and a third sub-region on which the third output circuit is located, and
wherein the first sub-region is arranged adjacently to the second region.

15. The apparatus of claim 14, wherein the second sub-region is arranged between the second region and the third sub-region.

16. The apparatus of claim 14, wherein the second sub-region is arranged between the first sub-region and the third sub-region.

17. The apparatus of claim 13, wherein the write clock driver circuit further includes a buffer circuit coupled between the dividing circuit and the second pre-stage circuit and configured to convey the divided clock signal to the second pre-stage circuit.

18. An apparatus comprising:
first, second, third, and fourth fast clock lines extending in a first direction;
first, second, third, and fourth slow clock lines extending in the first direction;
a clock dividing circuit configured to generate first, second, third, and fourth divided clock signals having different phases from one another; and
first, second, third, and fourth clock driver blocks arranged so as to surround the clock dividing circuit,
wherein the first clock driver block has a first fast clock driver configured to, based on the first divided clock signal, output a first fast clock signal having a first frequency to the first fast clock line and a first slow clock driver configured to, based on the first divided clock signal, output a first slow clock signal having a second frequency lower than the first frequency to the first slow clock line,
wherein the second clock driver block has a second fast clock driver configured to, based on the second divided clock signal, output a second fast clock signal having the first frequency to the second fast clock line and a second slow clock driver configured to, based on the second divided clock signal, output a second slow clock signal having the second frequency to the second slow clock line,
wherein the third clock driver block has a third fast clock driver configured to, based on the third divided clock signal, output a third fast clock signal having the first frequency to the third fast clock line and a third slow clock driver configured to, based on the third divided clock signal, output a third slow clock signal having the second frequency to the third slow clock line,
wherein the fourth clock driver block has a fourth fast clock driver configured to, based on the fourth divided clock signal, output a fourth fast clock signal having the first frequency to the fourth fast clock line and a fourth slow clock driver configured to, based on the fourth divided clock signal, output a fourth slow clock signal having the second frequency to the fourth slow clock line, and
wherein the first, second, third, and fourth fast clock drivers are located nearer than the first, second, third, and fourth slow clock drivers to the clock dividing circuit.

19. The apparatus of claim 18, further comprising first and second power supply circuits configures to supply a power voltage to the first, second, third, and fourth clock driver blocks,
wherein the first, second, third, and fourth clock driver blocks are arranged between the first and second power supply circuits.

20. The apparatus of claim 19, wherein each of the first and second power supply circuits includes a first switch circuit configured to supply the power voltage having a first voltage and a second switch circuit configured to supply the power voltage having a second voltage lower than the first voltage.
